(19) United States
(12) Patent Application Publication
(10) Pub. No.: US 2012/0168770 A1
(43) Pub. Date: Jul. 5, 2012

(54) HEAT DISSIPATION STRUCTURE OF CHIP

(75) Inventors: Ru Huang, Beijing (CN); Xin Huang, Beijing (CN); Tianwei Zhang, Beijing (CN); Qianqian Huang, Beijing (CN); Shiqiang Qin, Beijing (CN)

(73) Assignee: Peking University

(21) Appl. No.: 13/391,270

(22) PCT Filed: Nov. 18, 2011
(86) PCT No.: PCT/CN2011/082459

§ 371 Date: Mar. 21, 2012

(30) Foreign Application Priority Data
Dec. 3, 2010 (CN) 201010571866.X

(51) Int. Cl. H01L 29/20; H01L 29/12

(52) U.S. Cl. 257/76; 257/190; 257/E29.089; 257/E29.068

(57) ABSTRACT

A heat dissipation structure of a chip in the field of microelectronics is provided. The heat dissipation structure includes a P-type superlattice layer and an N-type superlattice layer formed over an upper surface of the chip by oxidation isolation. The P-type superlattice and the N-type superlattice are isolated by silicon oxide. Through a contact hole the P-type superlattice is electrically connected to a metal layer that is applied with a low potential in the chip, and a metal layer to be connected with an external power source is formed over the P-type superlattice. Through a contact hole the N-type superlattice is electrically connected to a metal layer that is applied with a high-potential power source in the chip, and a metal layer to be connected with an external power source is formed over the N-type superlattice. The potential of the external power source connected with the P-type superlattice is lower than that of the external power source connected with the N-type superlattice. The present invention can achieve heat dissipation of the chip and meanwhile prevent the ambient heat from transferring into the chip, by using the feature that the superlattice has a low thermal conductivity and phonon-localization-like behavior.

### FIELD OF THE INVENTION

The present invention relates to a field of microelectronics, particularly relates to a heat dissipation structure generally used in a semiconductor integrated circuit chip.

### BACKGROUND OF THE INVENTION

With the device dimension shrinking into nano-scaled region, the increasing device integration density together with the increasing clock frequency, result in large power consumption. The increased power consumption leads to increased chip temperature, which not only deteriorates performance of devices and circuits, but also affects reliability of devices and circuits. Nowadays, power density of a chip is around 100 W/cm², and it is likely to increase even further according to International Technology Roadmap for semiconductor guidelines.

Current ways of heat dissipating for a chip mainly include air cooling, water cooling, and thermoelectric cooling, and also include pipe cooling technology, microchannel cooling technology and a refrigeration technology based on the thermionic energy conversion effect. In the above methods, the previous three methods are relatively mature, in which heat dissipation efficiencies of the air cooling and the water cooling are lower than that of the thermoelectric cooling based on the Peltier effect, and the water cooling technology has a risk of fluid leakage.

### SUMMARY OF THE INVENTION

An object of the present invention is to provide a heat dissipation structure of a chip based on the Peltier thermoelectric effect.

A technical solution of an embodiment of the present invention is as follows.

A heat dissipation structure of a chip is characterized in that, a P-type superlattice layer and an N-type superlattice layer are formed over an upper surface of the chip by oxidation isolation, and the P-type superlattice and the N-type superlattice are isolated by silicon oxide; the P-type superlattice is electrically connected to a metal layer applied with a low potential in the chip via a contact hole, and a metal layer to be connected with an external power source is formed over the P-type superlattice; the N-type superlattice is electrically connected to a metal layer applied with a high-potential power source in the chip via a contact hole , and a metal layer to be connected with an external power source is formed over the N-type superlattice; and a potential of the external power source connected with the P-type superlattice is lower than that of the external power source connected with the N-type superlattice.

In the structure, the potential of the external power source connected with the P-type superlattice may be a ground potential, and the external power source connected with the N-type superlattice may have a high potential. Other metal conductive layers of the chip are connected with an external power source through a copper interconnection of a via hole. The copper interconnections and the superlattices are isolated by a silicon oxide.

The superlattices over the upper surface of the chip may employ a periodic structure including SiGe/Si, BiTe/SbTe, BiTe/BiTeSe, GaN/AlN, Si/SiO2 and so on. Thickness of the superlattices is about 1-3 μm. Doping concentrations of the superlattices are in a range of 10¹⁹-10²⁰ cm⁻³.

A buffer layer with a thickness of 1-2 μm is disposed between the superlattices and the chip. The buffer layer has a same doping concentration as the superlattices, so that a stress caused by a lattice mismatch between the superlattices and the chip is reduced. For example, a SiGe/Si superlattice may use SiGe/SiGeC as a buffer material.

Advantages and beneficial effects of an embodiment of the present invention are described below.

The present invention discloses a semiconductor heat dissipation structure based on the Peltier effect. The present invention can achieve the heat dissipation of the chip and meanwhile prevent the ambient heat from transferring into the chip, by using the feature that a superlattice has low thermal conductivity and phonon-localization-like behavior. When the chip is operating, a current flows from the N-type superlattice to the P-superlattice through a metal layer. At the same time of ensuring the operation of the chip, the heat dissipation of the chip is achieved by using the Peltier effect. The heat dissipation structure directly uses the main voltage of the chip, and there is no need to provide an additional power source voltage. Because of the feature that the superlattice has low thermal conductivity and phonon-localization-like behavior, the ambient heat can be prevented from transferring into the chip.

The present invention performs processes only on the surface of the chip but not the substrate of the chip, and hence a process step of protecting an upper surface of the chip when the substrate is processed is omitted. Furthermore, since a package technology of flipping chip is often used recently, performing the operation only on the upper surface of the chip can also prevent from forming holes on the whole chip, so that the process difficulty and the process complexity are alleviated. The fabrication process of the heat dissipation structure is compatible with the COMS process. Further, the process is performed in a longitudinal direction only, thus extra area of the chip is not occupied.

### BRIEF DESCRIPTION OF THE DRAWINGS

FIG. 1 is a cross-sectional view of a thermoelectric heat dissipation structure of a chip.

FIG. 2 are diagrams showing the fabrication flow of the thermoelectric heat dissipation structure of the chip.

100- the substrate of the chip

101- the operation region of the chip

102- a metal layer of a main power source (ground) of the chip

103- a metal layer of a main power source (with a high potential) of the chip

104- a contact hole for a superlattice and a metal conductive layer

105- a N-type superlattice

106- a P-type superlattice

107- a silicon oxide

108- an external power source V1

109- an external power source V2

110- a copper interconnection via

### DETAILED DESCRIPTION OF THE EMBODIMENTS

Hereafter, the present invention will be further described by examples. It is noted that embodiments disclosed are aimed to help further understand the present invention, and it will be apparent to those skilled in the art that various changes and modifications may be made without departing from the spirit and scope of the invention as defined in the following claims. Thus, the present invention should not be limited to the content disclosed by the embodiments, and the scope of the present invention is determined by the scope defined by the appended claims.

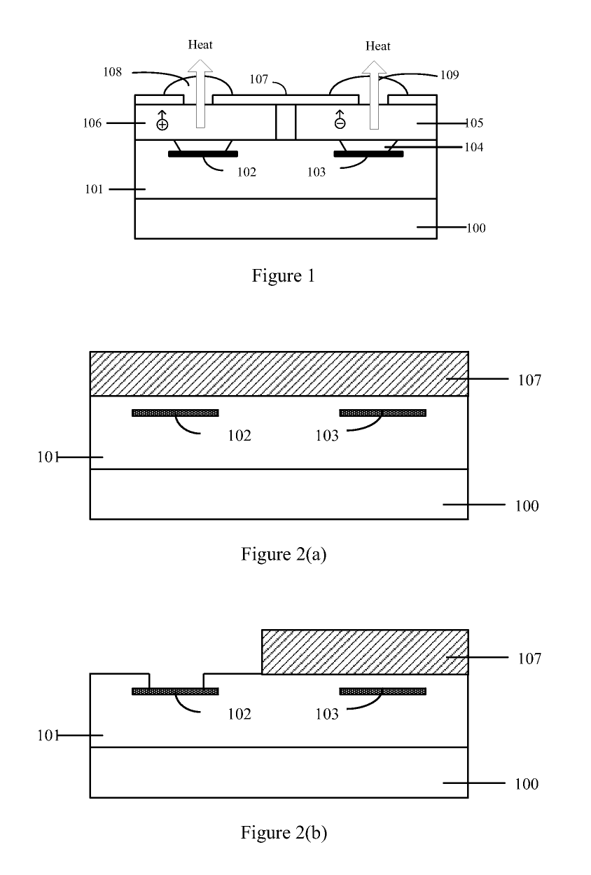

FIG. 1 is a cross-sectional view of a thermoelectric heat dissipation structure of a chip. The chip includes a substrate 100 and an operation region 101, wherein the operation region 101 of the chip includes polysilicon and metal interconnection lines. A P-type superlattice and an N-type super lattice are formed over the chip respectively, and the P-type superlattice and the N-type super lattice are isolated by silicon oxide. Through a contact hole, the P-type superlattice 106 is electrically connected to a metal layer that is applied with a low-potential (ground) power source (Vss) in the chip and a metal layer to be connected with an external power source (V1) is formed over the P-type superlattice. Through a contact hole the N-type superlattice 105 is electrically connected to a metal layer that is applied with a high-potential power source (Vdd) in the chip, and a metal layer to be connected with an external power source (V2) is formed over the N-type superlattice. The potential of the external power source V1 connected with the P-type superlattice is lower than that of the external power source V2 connected with the N-type superlattice.

A fabrication procedure of a heat dissipation structure of a chip includes the following steps.

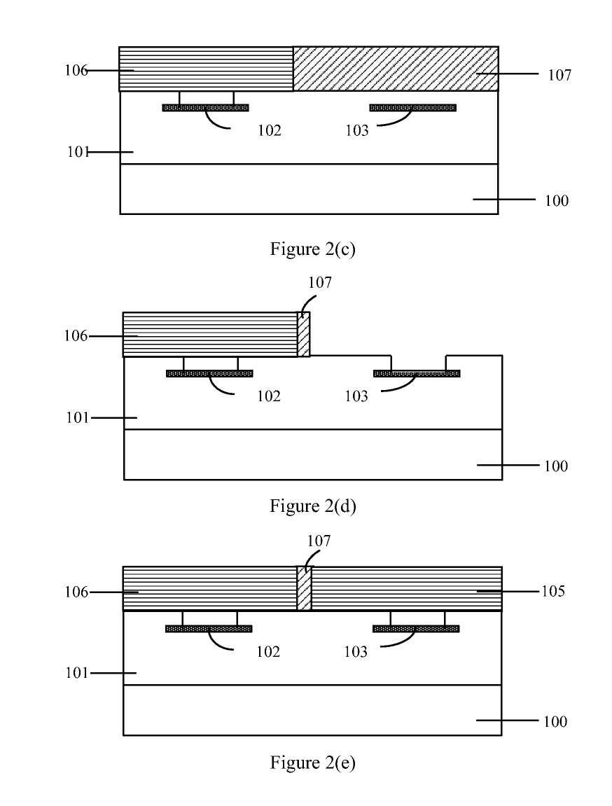

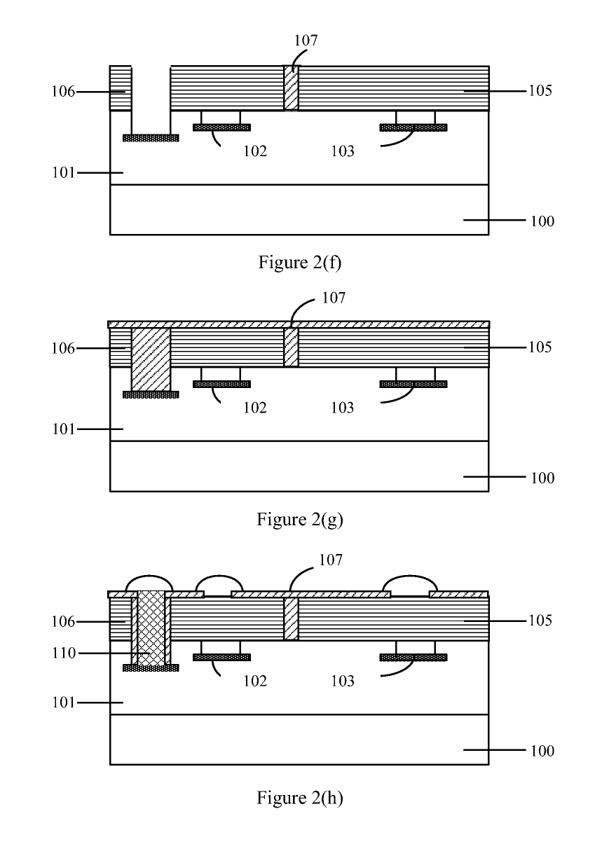

1. A silicon oxide isolation layer is deposited over the surface of the chip, as shown in FIG. 2(a).

2. A region of the silicon oxide at which a P-type superlattice is to be formed is removed, and a via is formed by etching to connect to a metal layer that is applied with a main power source of a low potential (ground) in the chip, as shown in FIG. 2(b).

3. The P-type superlattice is formed by molecular beam epitaxy, as shown in FIG. 2(c).

4. A region of the silicon oxide at which an N-type superlattice is to be formed is removed, and a portion of the silicon oxide is remained to be used as an isolation layer between the N-type superlattice region and the P-type superlattice region. A via is connected to a metal layer that is applied with a main power source of a high potential in the chip, as shown in FIG. 2(d).

5. The N-type superlattice is formed by molecular beam epitaxy, as shown in FIG. 2(e).

6. A via is formed by etching to connect other metal conductive layers in the chip, as shown in FIG. 2(f).

7. A silicon oxide isolation layer is deposited, as shown in FIG. 2(g).

8. The silicon oxide layer is etched, so that the P-type superlattice and the N-type superlattice are connected with an external power source of a low potential (ground) and an external power source of a high potential, respectively. Other metal conductive layers in the chip are connected with an external power source through a copper interconnection, as shown in FIG. 2(h).

When the voltages V1 and V2 are applied, according to the Peltier effect, portions (104) at which P-type superlattice and the N-type superlattice are contacted with the metal layers in the chip absorb heat, and the heat is dissipated from portions at which upper surfaces of the superlattices contacting with metal connection lines (108 and 109). Meanwhile, since the superlattices have low thermal conductivity and phonon-localization-like behavior, the ambient heat can be prevented from transferring into the chip. Therefore, the heat dissipation structure can cool the chip effectively.

1. A heat dissipation structure of a chip, wherein a P-type superlattice layer and an N-type superlattice layer are formed over an upper surface of the chip by oxidation isolation, and the P-type superlattice and the N-type superlattice are isolated by silicon oxide; through a contact hole the P-type superlattice is electrically connected to a metal layer that is applied with a low potential in the chip, and a metal layer to be connect with an external power source is formed over the P-type superlattice; through a contact hole the N-type superlattice is electrically connected to a metal layer that is applied with a high-potential power source in the chip, and a metal layer to be connected with an external power source is formed over the N-type superlattice; and the potential of the external power source connected with the P-type superlattice is lower than that of the external power source connected with the N-type superlattice.

2. The heat dissipation structure of the chip according to claim 1, wherein the potential of the external power source connected with the P-type superlattice is grounded, and the external power source connected with the N-type superlattice has a high potential; other metal conductive layers of the chip are connected with an external power source through a copper interconnection of the via; and the copper interconnection and the superlattices are isolated by silicon oxide.

3. The heat dissipation structure of the chip according to claim 1, wherein the superlattices over the upper surface of the chip employ a periodic structure comprising any of SiGe/Si, BiTe/SbTe, BiTe/BiTeSe, GaN/AlN and Si/SiO2; thicknesses of the superlattices are 1-3 μm; and doping concentrations of the superlattices are in the range of 1019-1020 cm-3.

4. The heat dissipation structure of the chip according to claim 1, wherein a buffer layer with a thickness of 1-2 μm is disposed between the superlattices and the chip, and the buffer layer has the same doping concentration as the superlattices.
